(19) United States
(12) Patent Application Publication
(10) Pub. No.: US 2017/0062639 A1
(43) Pub. Date: Mar. 2, 2017

(54) Direct Anchoring Solar Module System and Installation Method

(71) Applicant: Smash Solar, Inc., Richmond, CA (US)

(72) Inventors: Neil Goldberg, Berkeley, CA (US); Troy Douglas Tyler, El Cerrito, CA (US); David Schultz, Berkeley, CA (US); Bron Davis, Vacaville, CA (US); Eugene Kim, Orinda, CA (US)

(21) Appl. No.: 15/138,437

(22) Filed: Apr. 26, 2016

Related U.S. Application Data
(63) Continuation-in-part of application No. PCT/US16/00019, filed on Mar. 2, 2016.
Application No. PCT/US16/00019 is a continuation-in-part of application No. 14/521,245, filed on Oct. 22, 2014.
Application No. 14/521,245 is a continuation-in-part of application No. 14/054,807, filed on Oct. 15, 2013.
(60) Provisional application No. 62/152,938, filed on Apr. 26, 2015.
(60) Provisional application No. 62/127,287, filed on Mar. 2, 2015.
(60) Provisional application No. 62/152,938, filed on Apr. 26, 2015.
(60) Provisional application No. 62/197,564, filed on Jul. 27, 2015.
(60) Provisional application No. 62/203,304, filed on Aug. 10, 2015.
(60) Provisional application No. 62/203,902, filed on Aug. 11, 2015.
(60) Provisional application No. 62/209,860, filed on Aug. 25, 2015.
(60) Provisional application No. 62/260,321, filed on Nov. 26, 2015.
(60) Provisional application No. 61/712,878, filed on Oct. 12, 2012.

(51) Int. Cl. H01L 31/05

(52) U.S. Cl. CPC H01L 31/0516

(57) ABSTRACT

An integrated preassembled solar panel module includes a solar panel configured for receiving and converting solar radiation to produce electrical power. Multiple mounting feet are coupled to the solar panel at selected locations. One or more sheathing anchors are configured for coupling the mounting feet to roof sheathing at locations not overlapping roof rafters and thereby securing the solar panel to the roof sheathing without accessing an underside of the roof sheathing.

### PRIORITY AND RELATED APPLICATIONS

This application claims priority to U.S. provisional patent application Ser. No. 62/152,938, filed Apr. 26, 2015. This application is also a Continuation-in-Part (CIP) of PCT Application No. PCT/US16/00019, filed Mar. 2, 2016; which claims priority to U.S. provisional Ser. Nos. 62/127,287, filed Mar. 2, 2015; 62/152,938, filed Apr. 26, 2015, 62/197,564, filed Jul. 27, 2015, 62/203,304, filed Aug. 10, 2015, 62/203,902, filed Aug. 11, 2015, 62/209,860, filed Aug. 25, 2015, and 62/260,321, filed Nov. 26, 2015; and is also a continuation in part (CIP) which claims priority to U.S. patent application Ser. No. 14/521,245, filed Oct. 22, 2014, which is a continuation in part (CIP) which claims priority to U.S. patent application Ser. No. 14/054,807, filed Oct. 15, 2013, which claims priority to U.S. provisional patent application no. 61/712,878, filed Oct. 12, 2012. Each of the above priority and related applications is hereby incorporated by reference.

This application is also related to U.S. patent applications Ser. No. 14/521,245, filed Oct. 22, 2014; and Ser. No. 14/054,807, filed Oct. 15, 2013; PCT/US15/57018, filed Oct. 22, 2015; PCT/US13/65144, filed Oct. 15, 2013; and European application no. 13845553.0, filed Oct. 15, 2013. All of these priority and related applications are incorporated by reference.

### STATEMENT REGARDING FEDERALLY SPONSORED RESEARCH OR DEVELOPMENT

This invention was made with Government support under Award No. DE-EE0006457 and Award No. DE-EE0006693 awarded by the United States Department of Energy. The Government has certain rights in this invention.

### BACKGROUND

Solar panels are widely used in the production of electricity with multiple panels typically connected together as panel assemblies. These solar panel assemblies are usually arranged in arrays and mounted on structural racking systems on the roofs of buildings, on the ground or other fixed structures. A fixed structure can include, but is not limited to, existing residential or commercial roof tops, horizontal surfaces or vertical surfaces, existing fences, railings, walls or open ground-mounted areas. In many jurisdictions, these mounting systems must pass loading tests to ensure they can withstand static and dynamic loading anticipated during the life of the installation. These solar racking systems are often custom designed for each application and custom installed by contractors and tradespeople using specialty skills and following the approved drawings. This solar module system, in accordance with certain embodiments, meets the loading requirements of solar module racking systems through a flexible, configurable design that allows direct attachment either to the roof sheathing (plywood spanning over structural roof rafters or roof trusses that serves as a foundation for roofing materials) or to the roof rafters or roof trusses themselves. This flexible, configurable solar module system enables a streamlined installation method which eliminates expense of custom design and installation activities. This system reduces work on the roof and reduces the skills and experience potentially necessary on the roof to perform a high quality solar array installation.

In addition, a number of solar panel manufacturers have released new solar panels with integrated micro-inverters to simplify the electrical installation process. But a simple, low skill mechanical installation of a solar array remains unavailable on the market today.

Typical solar mounting or racking systems fail to provide the flexibility and the low skills many believe necessary for large scale adoption of solar power in the United States and around the world.

When typical threaded anchors, like wood screws or similar anchors, hold a solar panel or racking system to a roof through the roof sheeting, they can be prone to fail if the installer over tightens the anchor which results in the plywood stripping out and the anchor attachment losing its pull out value. Furthermore, typical through-wall anchors, like toggle anchors, are not designed for mounting through plywood. We have learned that the installation process for these through-wall anchors [FIG. 1] can be complicated and can abruptly stop if the blind nut (the nut located on the back side of the plywood partition) gets bound up when a bolt is being rotated into the blind nut.

Installers and system owners have no way of measuring the integrity of the structural anchoring of their solar mounting system. Especially when anchoring into rafters or trusses, it is very difficult to verify the integrity of structural anchoring into the rafter or truss.

Different composite shingle roofing products have a high degree of variability in course exposure and spacing. Anchoring a direct attachment system to such composite roofing systems may be difficult as the mounting points for the modules may not reliably align with the center of each roofing course where the flashing is located. Such misalignment could present a potential compromise of the waterproofing system involving roof flashing.

We have identified an issue that occurs when using the SNAPTOGGLE® brand of toggle bolts (U.S. Pat. Nos. 6,161,999 and 4,650,386, which are incorporated by reference) mounted through plywood or orientated strand board (OSB) plywood—especially in a roof top application. The issue is that the SnapToggle toggle anchor occasionally spins in the hole when a worker is driving the bolt into the toggle to tighten it. Also, the ¼″ toggle anchor may deform under load during specific testing scenarios.

The solar power industry installs solar on various types of roofing systems. These systems include composite shingle roofing, flat tile roofing, s-tile roofing, metal roofing and flat roofing. According to the 2009 US Energy Information Agency's Residential Energy Consumption Survey (RECS), major roofing materials for single family residences are, in order of number installed, composite shingle, asphalt, metal, wood shingles/shakes, ceramic or clay tile, concrete tile and slate. Therefore, the solar industry needs a solar module system that can support a majority of these roofing materials.

### BRIEF DESCRIPTION OF THE DRAWINGS

FIG. 1 illustrates a Toggler Snaptoggle® toggle anchor (reference U.S. Pat. Nos. 6,161,999 and 4,650,386.)

FIG. 2 illustrates an improvement to the Toggler Snaptoggle® toggle anchor that adds barbs or teeth on the plywood side of the toggle. Also, an increase in sheet metal gauge and/or an increase in length of toggle is made to increase pullout strength of toggle.

FIGS. 3A-3B illustrate a second embodiment of a sheathing anchor for anchoring to the “sheathing strong points” with a deep toggle with teeth [12] and a direct, pivoting engagement with the threaded bolt [13].

FIGS. 4A-4D illustrates a third embodiment of a sheathing anchor showing both exterior elevations of the standard hex bolt [13], rubber stop [14] (used to hold the toggle/bolt assembly while the user is rotating the bolt into the toggle anchor) and the pivoting toggle/threaded collar [15].

FIGS. 5A-5C illustrates a rendering of the third embodiment of SMASHtoggle showing different exterior elevations of the hex bolt [13], the rubber or other natural or synthetic compliant material (used for both waterproofing and a stop to hold the bolt/toggle assembly during the user's rotating of the bolt into the toggle anchor) and the toothed toggle sprung to stay a few degrees from in line of the bolt—as in the second image (for entry into the pilot hole) or sprung to stay fully open—as in third image (to become fully lockable after the toggle pushes through the pilot hole).

FIGS. 6A-6C illustrates a stacking element for solar power modules built into the mounting bracket [6] snap couplers [7] and [8]. Specifically, the snap locking mechanism [16] may serve as a stacking element for transit of the direct anchoring solar power modules.

FIGS. 7A-7D illustrate a different embodiment of a stacking element for solar power modules built into the mounting bracket [6] at the snap couplers [7] and [8]. Stacking element at the female coupler [17] and another stacking element at the male coupler [18] both support the solar power module when stacking for shipment.

FIGS. 8A-8B illustrates an embodiment including a Composite Shingle Roof application including an array of 4 modules, interleafed and interlocked with corresponding adjacent modules at location 1, 2, 3 and 4 with anchoring feet in adjusted position.

FIGS. 9A-9B illustrates an embodiment including a Mounting Bracket Assembly.

FIGS. 10A-10B illustrates an embodiment including a Side view of solar panel module.

FIGS. 11A-11B illustrates an embodiment including a Plan view of solar panel module assembly.

FIGS. 12A-12B illustrates an embodiment including a cross section view Section A—Section through Full Assembly.

FIGS. 13A-13B illustrates an embodiment including a cross section of a solar panel module, Section B—Section through Full Assembly.

FIGS. 14A-14D illustrates an embodiment including an Interlocking Mounting System for Solar Panels (Back View).

FIGS. 15A-15B illustrates an embodiment including a cross-sectional view of Panel Track with Mounting Bracket beyond for a solar panel module.

FIGS. 16A-16B illustrates an embodiment including a cross-sectional view through Cable Tray hanging on Panel Track for a solar panel module.

FIGS. 17A-17B illustrates an embodiment including a Mounting Bracket and adjustable Mounting Foot Assembly of a solar panel module for pitched roof applications.

FIGS. 18A-18B illustrates an embodiment including a cross-sectional view of a Mounting Bracket and adjustable Mounting Foot Assembly of a solar panel module for pitched roof applications.

FIGS. 19A-19C illustrates an embodiment including an Interlocking Mounting System for Solar Panels with configurable Mounting Brackets (Back View).

FIGS. 20A-20B illustrates an embodiment including an Interlocking Mounting System for Solar Panels with configurable Mounting Bracket components in use (Back View).

FIGS. 21A-21D illustrates an embodiment including a Configurable Mounting Bracket Assembly for a solar panel module—Exploded Component Diagram.

FIGS. 22A-22D illustrates an embodiment including an Adjustable Mounting Foot Assembly for a solar panel module and Flashing for pitched roof applications.

### DETAILED DESCRIPTIONS OF THE EMBODIMENTS

This solar module system, in accordance with certain embodiments, solves the problems above through a comprehensive solar module system designed to streamline the installation of solar by using a direct attachment method to sheathing or roof rafters or roof trusses.

A solar module system, in accordance with certain embodiments, eliminates the need to precisely layout and install roof connectors at the roof rafters.

A solar module system, in accordance with certain embodiments, reduces the size of the crew required to install a solar array. The solar module system, in accordance with certain embodiments, can be installed with a minimal number of workers in a fraction of the time that a conventional solar system takes to install.

A solar module system, in accordance with certain embodiments, mitigates the risk of a failed anchor installation—in which a threaded anchor is over tightened in sheathing or an anchor is incorrectly installed into a rafter—by using a special toggle designed specifically for plywood or OSB applications.

A solar module system, in accordance with certain embodiments, eliminates roof connectors for solar modules (sometimes called roof jacks or roof connector) as the mounting bracket serves as the point of attachment of the solar module to the roof.

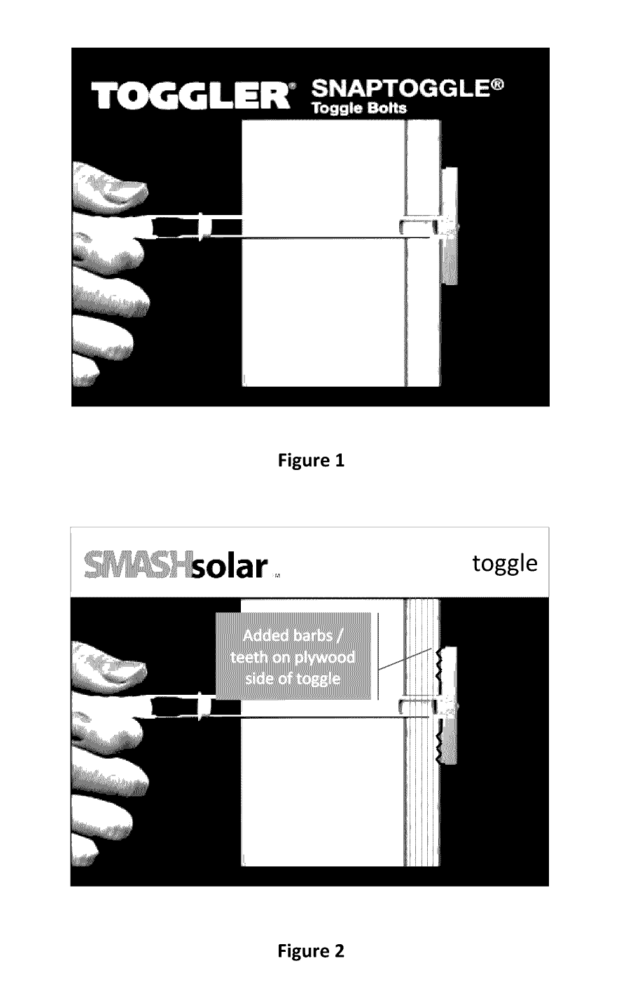

FIG. 1 illustrates a Toggler Snaptoggle® toggle anchor. U.S. Pat. Nos. 6,161,999 and 4,650,386 are hereby incorporated by reference.

FIG. 2 illustrates an improvement to the Toggler Snaptoggle® toggle anchor that adds barbs or teeth on the plywood side of the toggle. Also, an increase in sheet metal gauge and/or an increase in length of toggle is made to increase pullout strength of toggle.

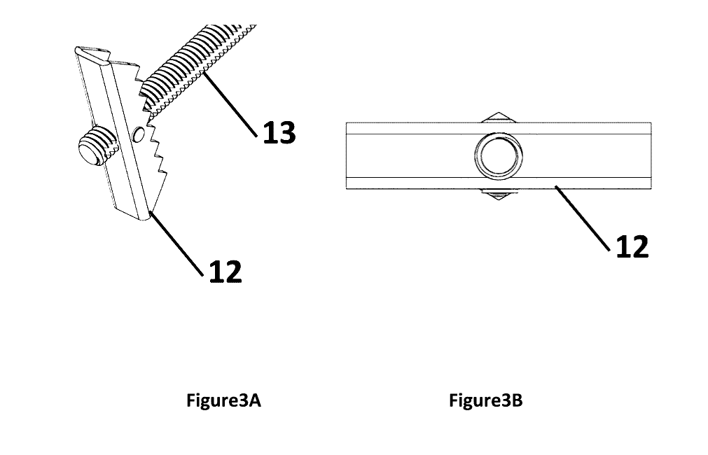

FIGS. 3A-3B illustrate a second embodiment of a toggle anchor for anchoring to the “sheathing strong points” with a deep toggle with teeth [12] and a direct, pivoting engagement with the threaded bolt [13].

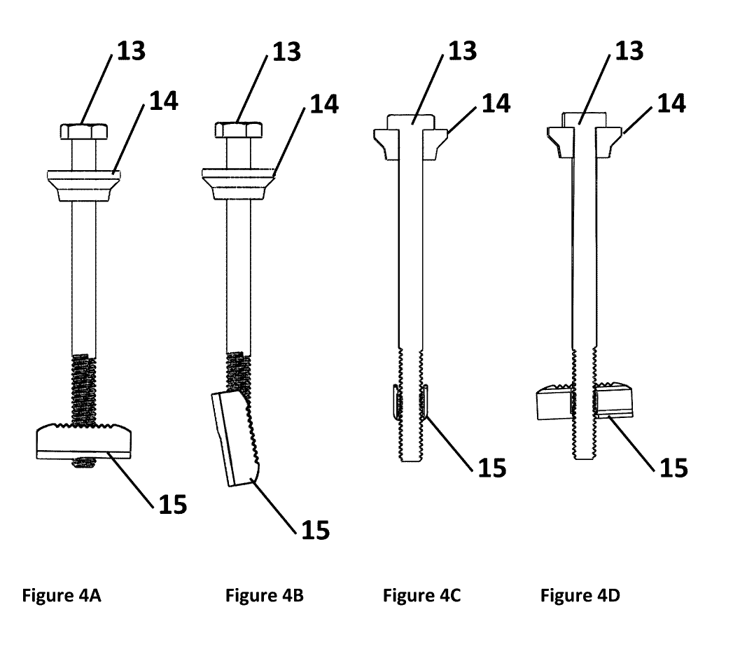

FIGS. 4A-4D illustrate a third embodiment of a toggle anchor showing both exterior elevations of the standard hex bolt [13], rubber stop [14] (used to hold the toggle/bolt assembly while the user is rotating the bolt into the toggle anchor) and the pivoting toggle/threaded collar [15].

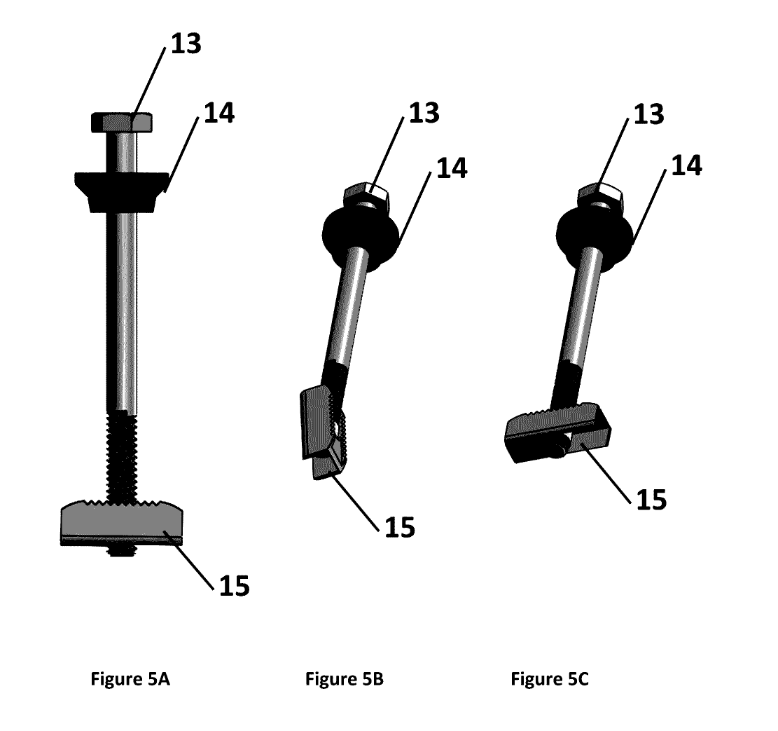

FIGS. 5A-5C illustrate a rendering of the third embodiment of SMASHtoggle showing different exterior elevations of the hex bolt [13], the rubber or other natural or synthetic compliant material (used for both waterproofing and a stop to hold the bolt/toggle assembly during the user's rotating of the bolt into the toggle anchor) and the toothed toggle sprung to stay a few degrees from in line of the bolt—as in the second image (for entry into the pilot hole) or sprung to stay fully open—as in third image (to become fully lockable after the toggle pushes through the pilot hole).

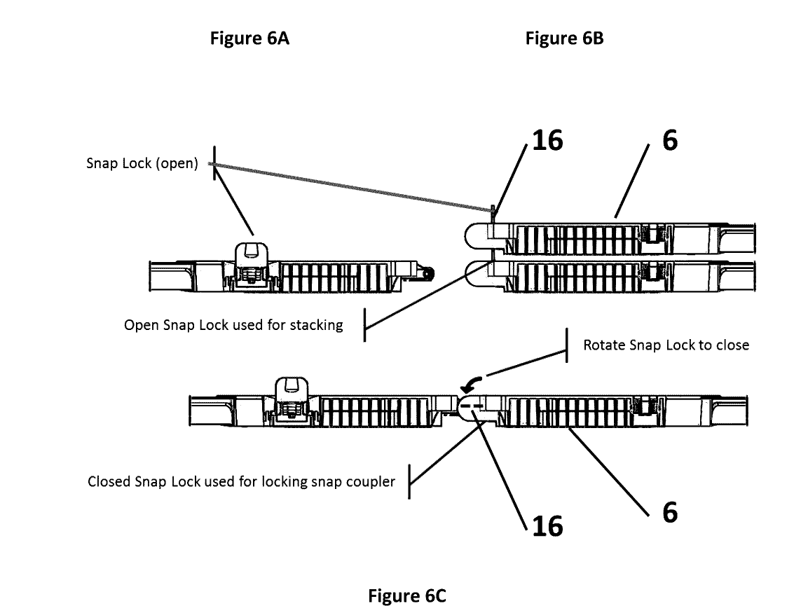

FIGS. 6A-6C illustrate a stacking element for solar power modules built into the mounting bracket [6] snap couplers [7] and [8]. Specifically, the snap locking mechanism [16] may serve as a stacking element for transit of the direct anchoring solar power modules.

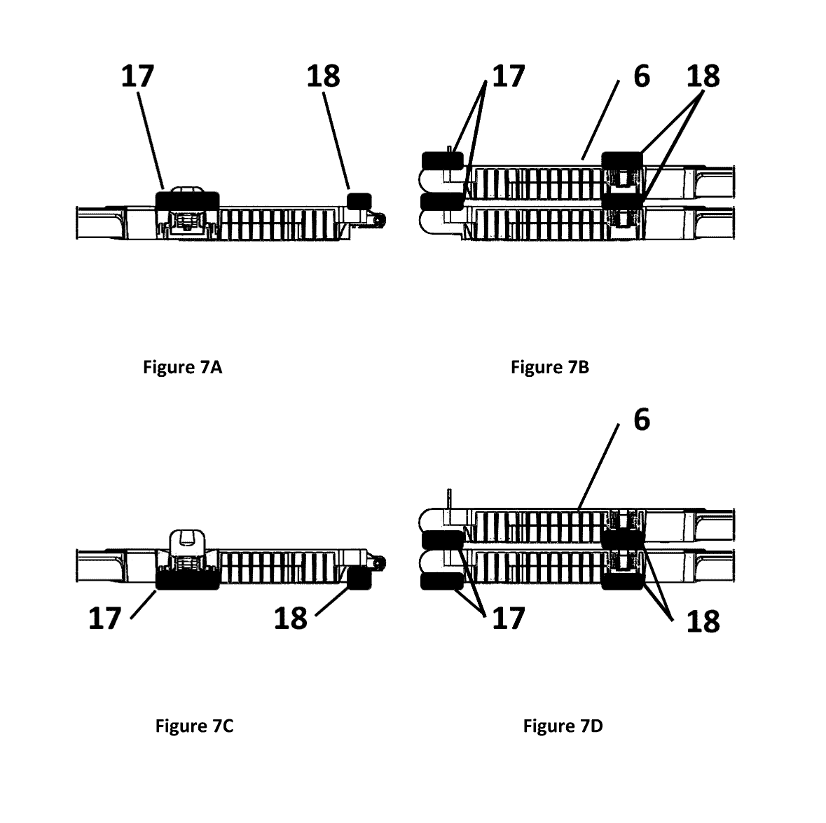

FIGS. 7A-7D illustrate a different embodiment of a stacking element for solar power modules built into the mounting bracket [6] at the snap couplers [7] and [8]. Stacking element at the female coupler [17] and another stacking element at the male coupler [18] both support the solar power module when stacking for shipment.

TOGGLE ANCHORS: This solar module system, in accordance with certain embodiments, can, in some cases, benefit from reliable through-wall anchors or toggle anchors. Such embodiments can have the following characteristics.

An issue occurs when using the SNAPTOGGLE® brand of toggle bolts (U.S. Pat. Nos. 6,161,999 and 4,650,386) [FIG. 2] through plywood or orientated strand board (OSB) plywood—especially in a roof top application. The issue is that the SnapToggle toggle anchor occasionally spins in the hole when a worker tries to drive the bolt into the toggle to tighten it. Our first embodiment of an improvement to the SnapToggle product [FIGS. 3A-3B] adds features to engage with the plywood or OSB sheathing under the roofing material to prevent the anchor from spinning. Some embodiments to achieve this goal are illustrated and some are described including: teeth, barbs or other features on the toggle anchor [12], resizing the toggle anchor [12] in length, width or thickness or change other characteristics. This refined toggle anchor [12] could be coupled to a threaded bolt [13] using a threaded collar or other means.

In FIGS. 4A-4D and FIGS. 5A-5C, another embodiment to the toggle anchor is described.

FUNCTION: The primary functions of the toggle anchor include the following:

This toggle anchor is designed to securely and easily mount to plywood, wood, fiberboard, drywall or other sheet materials, especially those in a wet environments.

The operation of the toggle anchor has a minimal number of steps and a low user skill level for successfully securing a mechanical component to a pitched or vertical surface.

The toggle anchor may insert into a pilot hole and get tightened with the attached threaded bolt without any interruption in the operation of the anchor and bolt (e.g. anchor spinning uncontrollably).

The toggle anchor [15] may be either sprung open or sprung closed depending on the particular application, for example, as illustrated at FIGS. 4A-4D and FIGS. 5A-5C.

COMPOSITION: The toggle anchor can be made from any mechanically appropriate material that can resist corrosion inherent in an exterior application like a pitched roof or vertical application. Typically materials with such characteristics could be stainless steel or galvanized steel. The exception to this material composition is the integral plug [14] which would be a more compliant material that could also have material characteristics to deflect, prevent and resist water infiltration. Some materials that may fit these requirements may include rubber, EPDM and other natural and synthetic materials.

CONFIGURATION: The dimensions of the toggle anchors can vary depending on the specific solar panel's physical characteristics and mechanical requirements. The toggle anchors therefore can take any number of sizes (lengths or diameters) or configurations. Specifically, the following attributes are known:

The toggle anchor's toggle [15] may have barbs or teeth or other features to secure it from spinning when the user is driving a bolt into the toggle.

The toggle anchor's toggle [15] may have an integral threaded barrel or collar to attach to a standard hex bolt (e.g. ⅜″ or ¼″ bolt).

The assembly of the toggle anchor includes an integral plug [14] to hold the toggle anchor assembly in place while the user drives the bolt [13] into the toggle [15] (and to provide a secondary waterproofing barrier).

The toggle anchor's toggle [15] may employ a spring feature to hold the toggle anchor a minimal number of degrees from the centerline of the bolt [13](for easier inserting through the hole)—as in the second image of FIG. 5B.

The toggle anchor's toggle may employ a spring feature to stay fully open—as in the first and third images of FIGS. 5A and 5C (to become fully seated against the penetrated material after the toggle pushes through the pilot hole).

STACKING FEATURES: This solar module system, in accordance with certain embodiments, can, in some cases, benefit from modules transported safely and securely with minimal risk of damage during shipping and handling. To that end, the solar module system, in accordance with certain embodiments, can have the following key characteristics:

(a) Bumpers and other features to protect the module corners and other exposed edges. In FIGS. 6A-6C, the mounting bracket [6] has male [7] and female [8] coupling mechanisms and an anchor support system [9]. Each of these elements have components that may have specific features designed to keep the module edge safe from abrasion and damage.

(b) In addition to bumpers, the mounting bracket design provides functional elements to support the stacking of direct anchoring solar modules for shipping.

COMPOSITION: The stacking and protection features of the direct anchoring solar module system may be incorporated into the mounting bracket [6] design and could be composed of the same materials as the mounting bracket [6] (previously defined).

CONFIGURATION: The dimensions of the stacking and protection features of these embodiments may vary depending on the specific solar panel's physical characteristics and mechanical requirements. The stacking and protection features therefore can take any number of sizes or configurations. As illustrated in FIGS. 7A-7D, the stacking blocks may be configured above or below the mounting bracket. Specifically, the following attributes are known:

At one or more points on the mounting bracket [6] a feature may exist for a second mounting bracket from a module above to rest on the subject mounting bracket.

The stacking and protection feature system may mechanically support the same or greater number of modules per pallet as existing standard modules and their stacking features support per pallet.

The stacking and protection features could be incorporated into the snap lock [16] as shown in the example of FIGS. 6A-6C or into the male coupling [18] or female coupling [17] as shown in the example of FIGS. 7A-7D.

ADDITIONAL TOGGLE ANCHOR EMBODIMENTS: This solar module system, in accordance with certain embodiments, can, in some cases, benefit from reliable, easy to install, easy to manufacture through wall anchors or “toggle anchors”. Such embodiments can have the following characteristics.

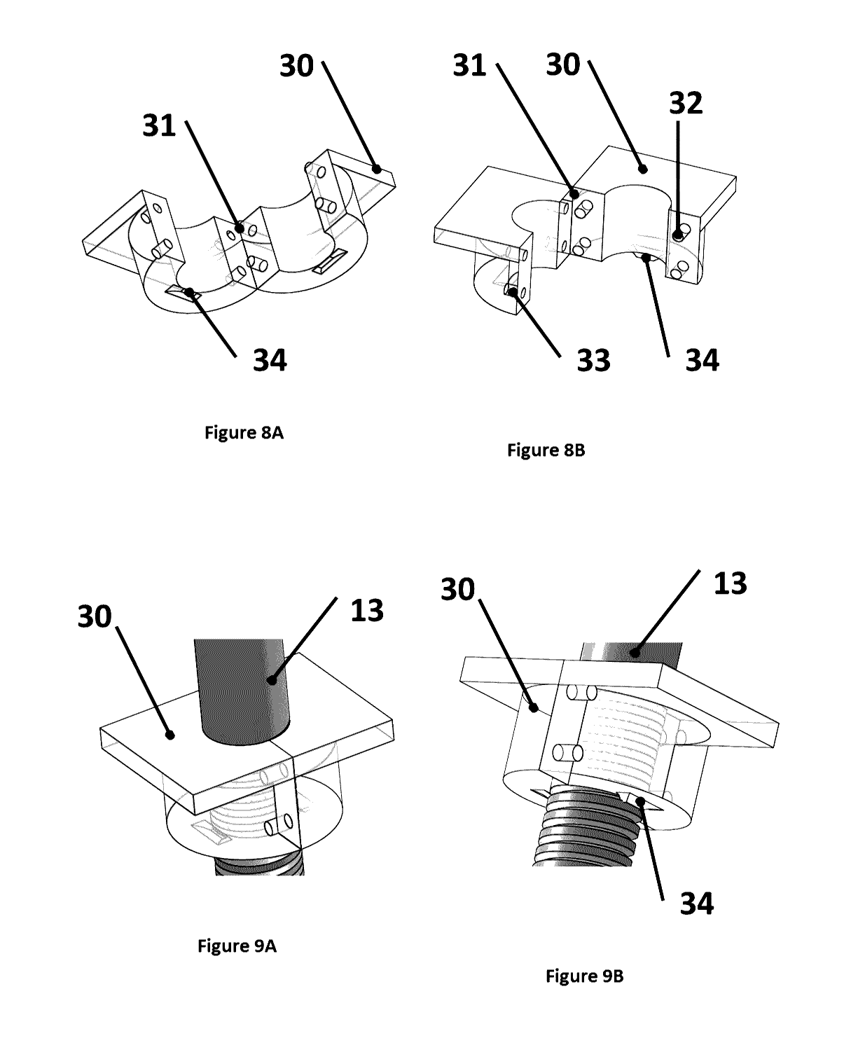

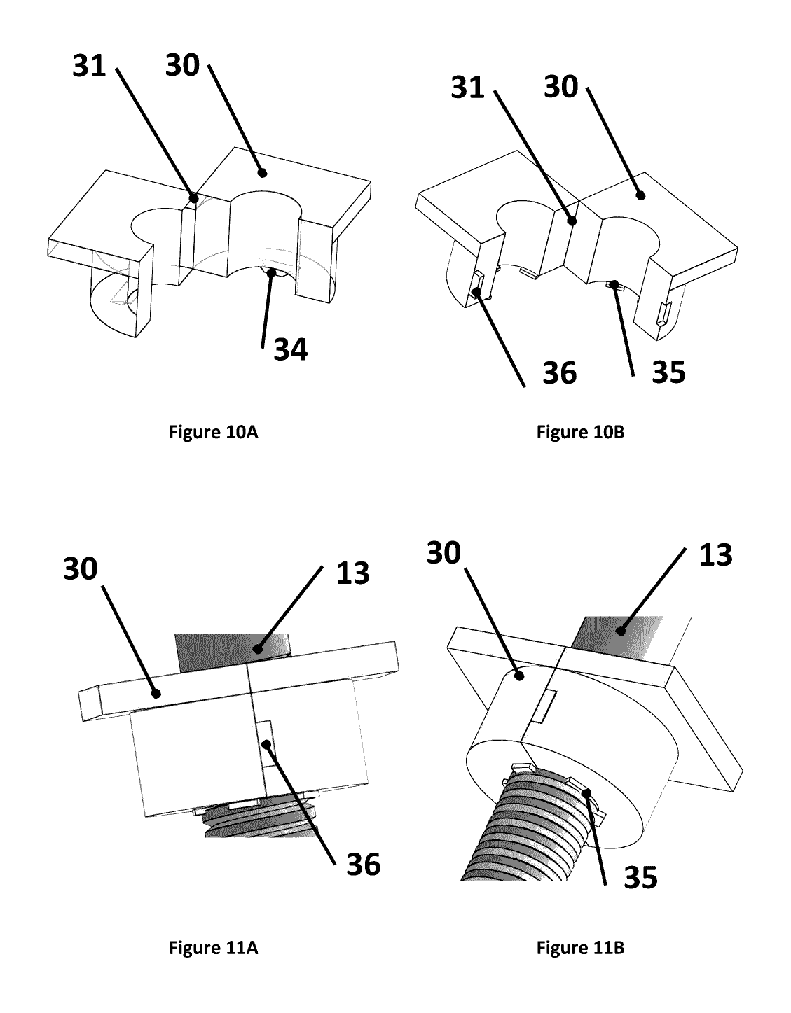

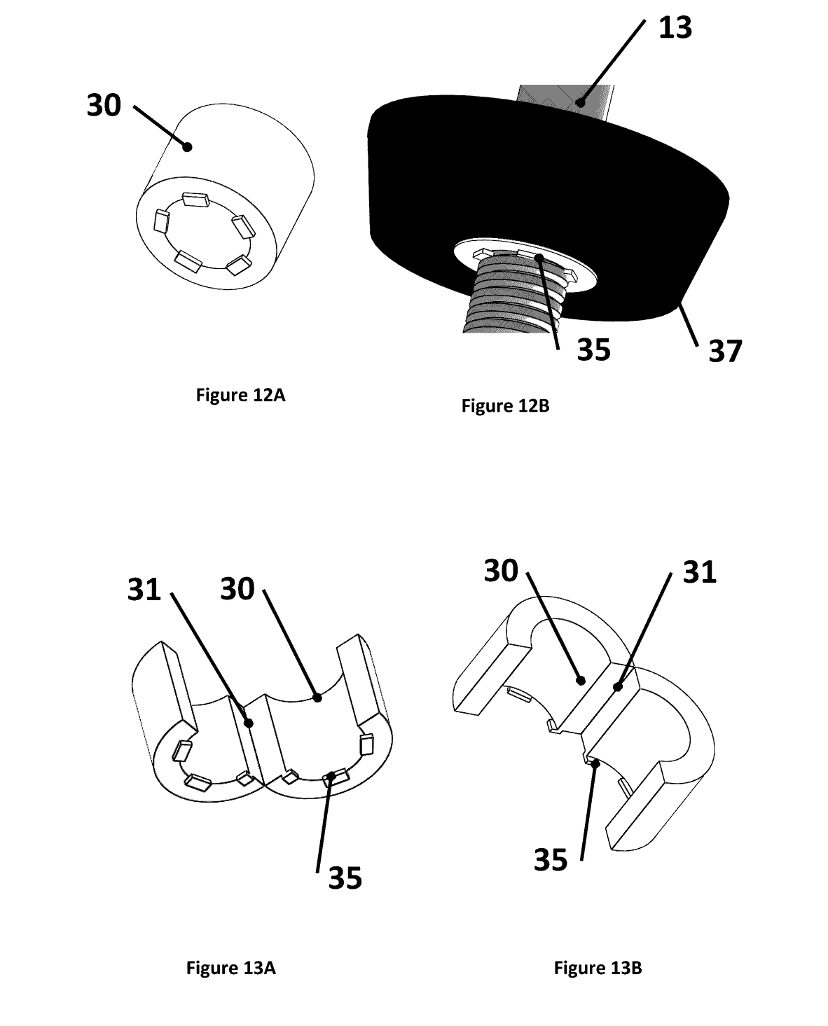

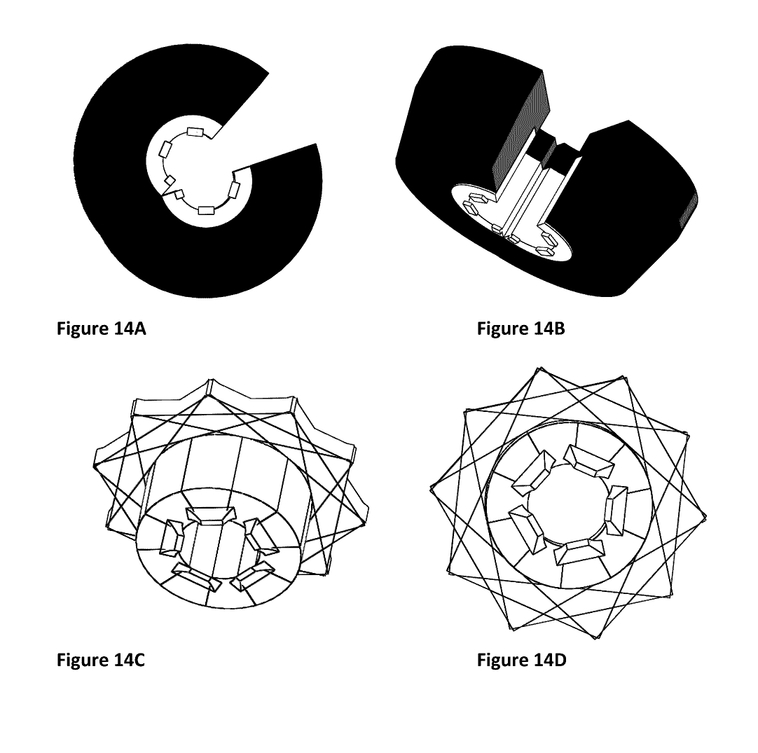

A primary issue occurs when producing a “toggle anchor” that the manufacture of parts can get complicated and it can be difficult to keep a “toggle anchor” easy to use. In FIGS. 8A-8B, examples of additional embodiments of the integral plug originally defined in [14] are illustrated. In this embodiment, the integral plug is produced as an upper collar [30] with a living hinge [31] combining two halves of the collar one with male pins [32] and one with female holes [33] to accept the male pins in assembly. Each side has an extension feature [34] to engage with the threaded bolt [13]—note this extension feature [34] could reside at the top or the bottom of the upper collar [30]. FIGS. 9A-9B illustrate an example of the upper collar [30] assembled around the threaded bolt [13]. In an alternate embodiment of the upper collar [30], FIGS. 10A-10B and FIGS. 11A-11B illustrate an example of a collar [30] with an alternative clasp [36] and an alternative extension feature [35]. As an alternative embodiment of the upper collar [30], FIGS. 12A-12B and FIGS. 13A-13B illustrate another example of a collar [30] made up of a ring and a plug [37] combination. The ring collar [30] has integral extension features [35]. In FIGS. 14A-14D, examples of additional embodiments of the upper collar [30] are illustrated.

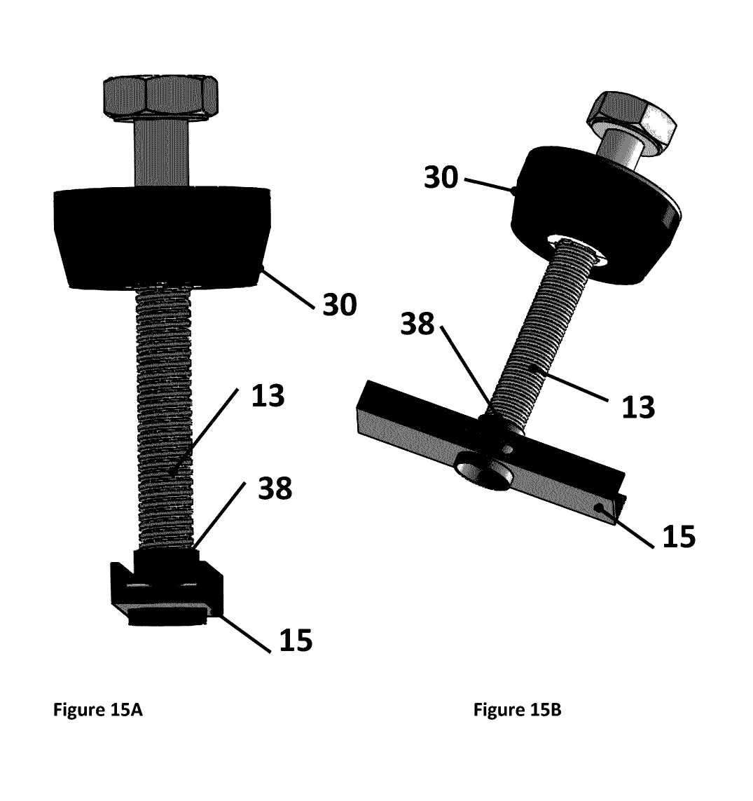

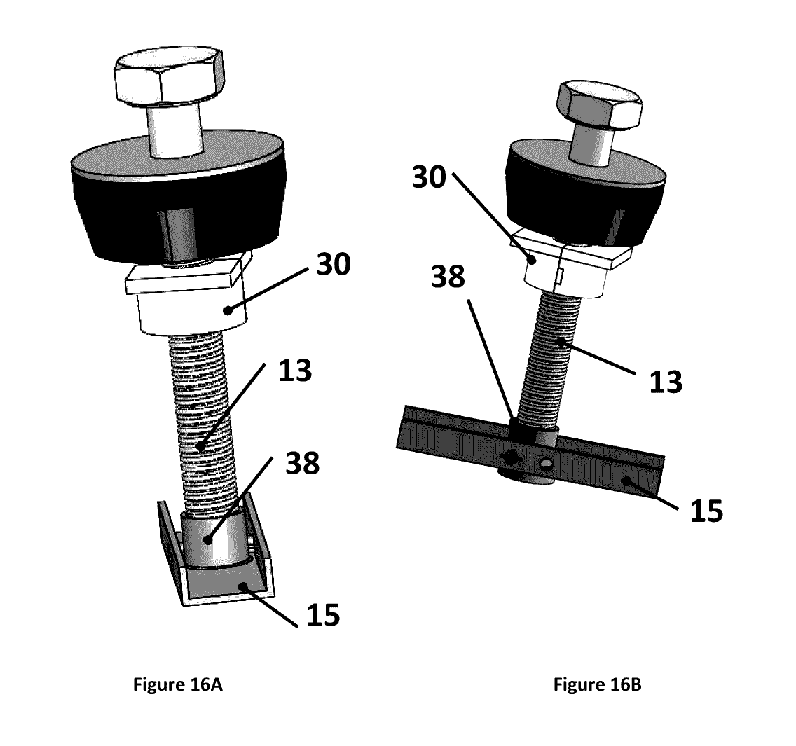

An example in an assembly of the upper collar [30] and the threaded bolt [13] and the toggle anchor [15] are illustrated in FIGS. 15A-15B. In addition a lower collar [38] is introduced that serves to hold the toggle anchor [15] on to the threaded bolt [13]. Also, in FIGS. 16A-16B, examples of similar assemblies to those in FIGS. 15A-15B are illustrated but with the upper collar [30] added for clarity.

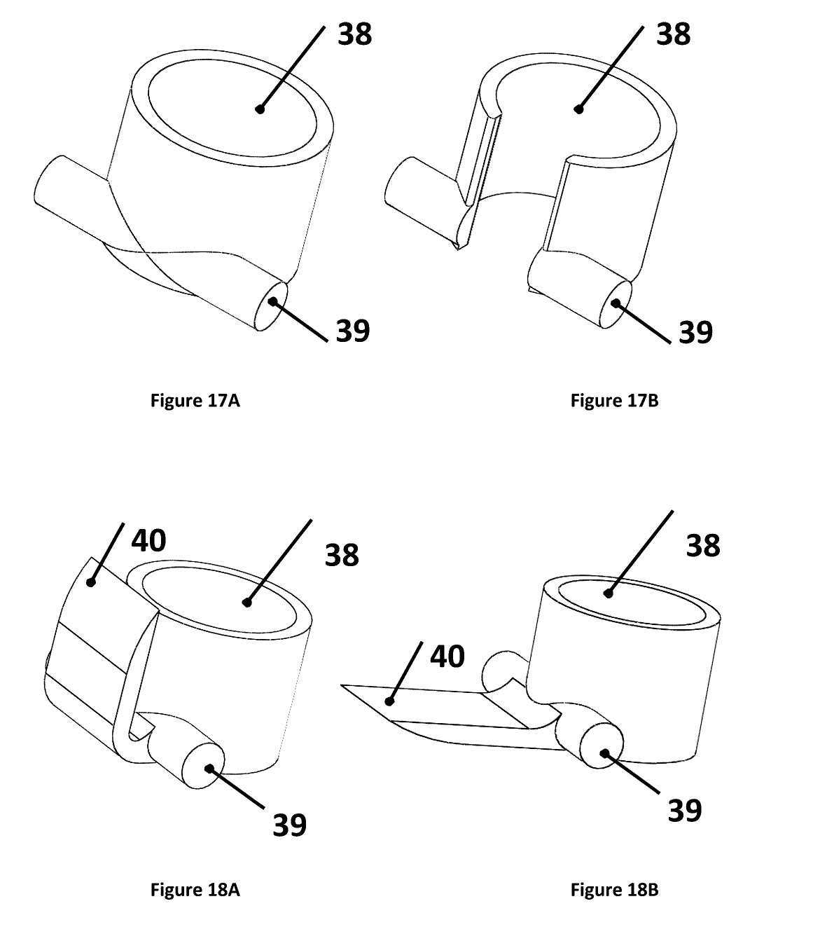

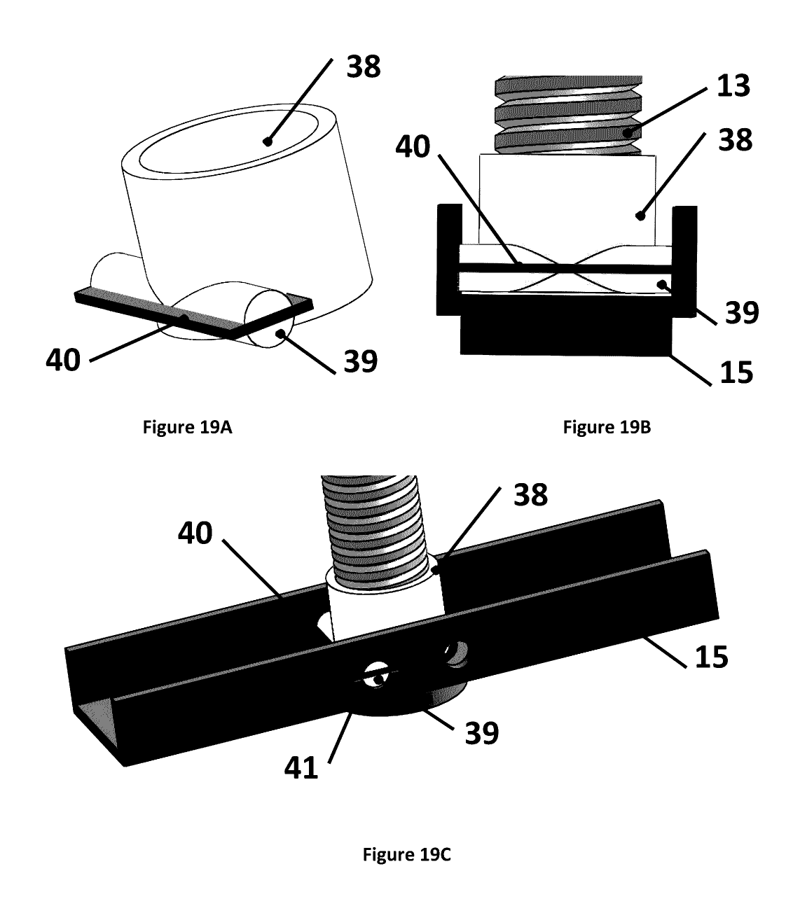

The lower collar [38] has several embodiments each different construction to achieve unique characteristics of holding the toggle anchor fastened to the threaded bolt and providing a spring to allow automatic alignment of the toggle anchor with the threaded bolt. In FIGS. 17A-17B, examples of two embodiments of the lower collar are illustrated [38] each having pins [39] that couple with the toggle anchor. In FIGS. 18A-18B, examples of embodiments of the lower collar [38] are illustrated, each having an integral spring [40] to align the toggle anchor with the threaded bolt. In FIGS. 19A-19C, examples of another embodiment of the lower collar [38] are illustrated which incorporates the pin [39] into the toggle anchor [15] and an integrated leaf spring [40] into the lower collar body [38]. In the assembly of the threaded bolt [13] and the toggle anchor [15], the lower collar [38] inserts into the toggle anchor [15] with a special feature [41] in the toggle anchor body to securely engage the leaf spring [40].

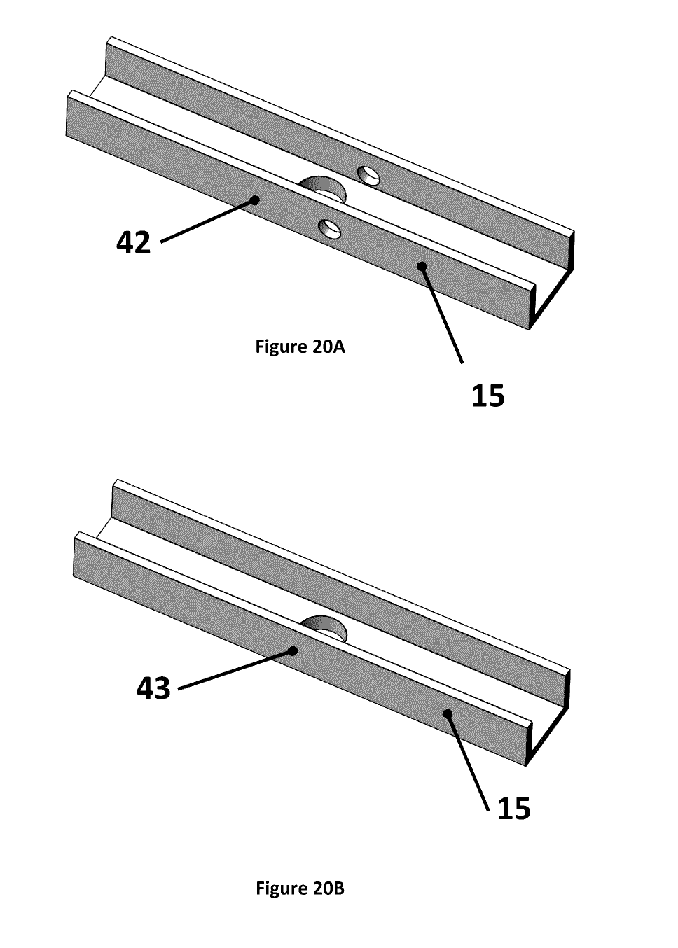

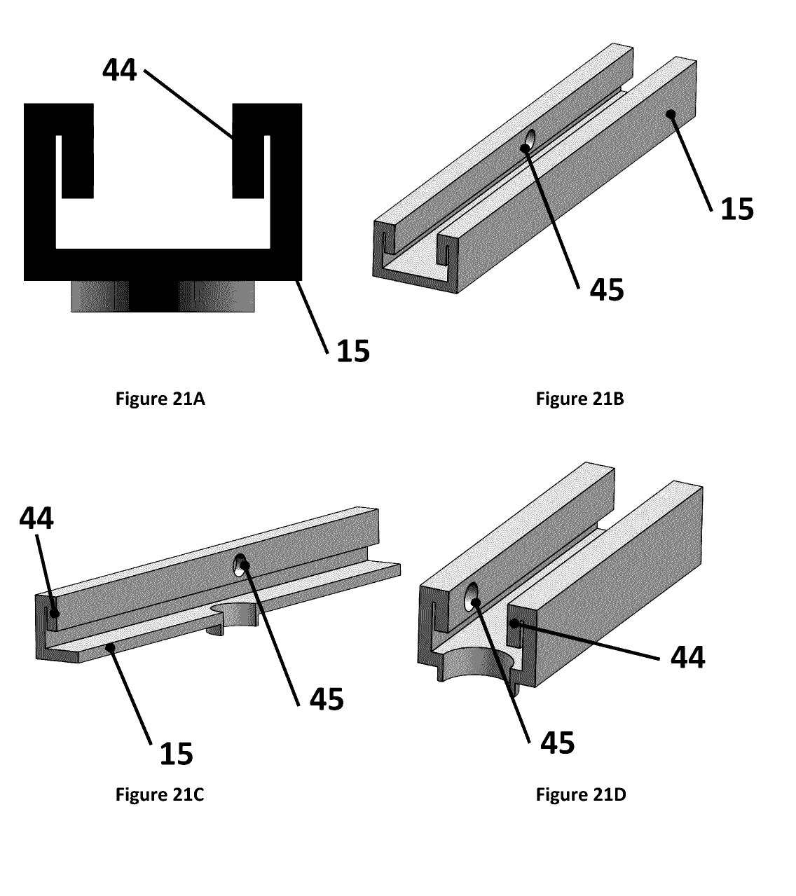

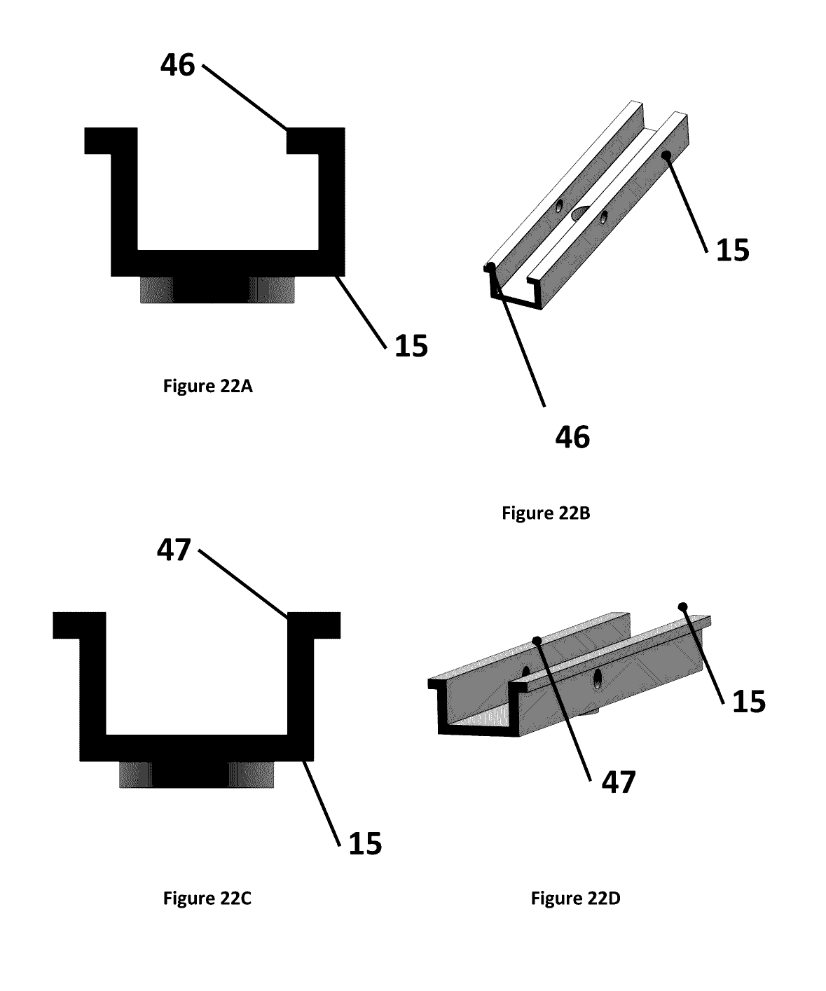

As we consider the challenges of the existing art for toggle anchors [15] typically, we have learned that they can bend or buckle under certain load conditions—especially in a roofing environment. In FIGS. 20A-20B, examples of embodiments of the toggle anchor are illustrated with features that strengthen the toggle in performance under load. In FIGS. 20A-20B, examples of two features of the side flange of each toggle anchor [15] are illustrated. First, we show only one hole [42] along the side flange of the toggle anchor [15]. Next we show no holes [43] along the side flange of the toggle anchor. FIGS. 21A-21D illustrate examples of toggle anchor features that provide an engagement for the lower collar pin [39] such as the folded side flange [44]. The interior hole [45] which would engage with the lower collar pin [39]. These features serve to strengthen the toggle anchors for structural loading conditions. FIGS. 22A-22D illustrate examples of alternative side flange details to provide additional strength in the toggle anchor [15]. These features include a detail in which one (1) of the top of the side flanges is bent out and one (1) of the top of the side flanges is bent in [46] to form a pair of flat top flanges and a feature in which both of the top of the side flanges is bent out [47] to form a pair of flat top flanges.

In certain embodiments, a 0.25 inch bolt and toggle may be used together to couple a solar panel module to a roof sheathing through. Half in hole in the sheathing, wherein the toggle has a 0.05 inch or greater gauge thickness. In certain embodiments, a ⅜ inch bolt or 5/16 inch bolt or half inch bolt and toggle may be used together to couple a solar panel module to a roof sheathing through a ¾″ hole in the sheathing, wherein the toggle has a 0.0615 inch or greater gauge thickness. In certain embodiments, a toggle may have a length 2.125 inches or greater.

Various modifications and alterations of the invention will become apparent to those skilled in the art without departing from the spirit and scope of the invention, which is defined by the accompanying claims. It should be noted that steps recited in any method claims below do not necessarily need to be performed in the order that they are recited. Those of ordinary skill in the art will recognize variations in performing the steps from the order in which they are recited. In addition, the lack of mention or discussion of a feature, step, or component provides the basis for claims where the absent feature or component is excluded by way of a proviso or similar claim language.

While various embodiments of the present invention have been described above, it should be understood that they have been presented by way of example only, and not of limitation. The various diagrams may depict an example architectural or other configuration for the invention, which is done to aid in understanding the features and functionality that may be included in the invention. The invention is not restricted to the illustrated example architectures or configurations, but the desired features may be implemented using a variety of alternative architectures and configurations. Indeed, it will be apparent to one of skill in the art how alternative functional, logical or physical partitioning and configurations may be implemented to implement the desired features of the present invention. Also, a multitude of different constituent module names other than those depicted herein may be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead may be applied, alone or in various combinations, to one or more of the other embodiments of the invention, whether or not such embodiments are described and whether or not such features are presented as being a part of a described embodiment. Thus the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the such as; the term “example” is used to provide exemplary instances of the item in discussion, not an exhaustive or limiting list thereof; the terms “a” or “an” should be read as meaning “at least one,” “one or more” or the such as; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Hence, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the invention may be described or claimed in the singular, the plural is contemplated to be within the scope thereof unless limitation to the singular is explicitly stated.

The presence of broadening words and phrases such as “one or more,” “at least,” “but not limited to” or other such as phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, may be combined in a single package or separately maintained and may further be distributed across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives may be implemented without confinement to the illustrated examples. For example, block diagrams and their accompanying description should not be construed as mandating a particular architecture or configuration.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

Thus, for example, it will be appreciated by those of ordinary skill in the art that the diagrams, schematics, illustrations, and such as represent conceptual views or processes illustrating systems and methods in accordance with particular embodiments. The functions of the various elements shown in the figures may be provided through the use of dedicated hardware as well as hardware capable of executing associated software. Similarly, any switches shown in the figures are conceptual only. Their function may be carried out through the operation of program logic, through dedicated logic, through the interaction of program control and dedicated logic, or even manually, the particular technique being selectable by the entity implementing this invention. Those of ordinary skill in the art further understand that the exemplary hardware, software, processes, methods, and/or operating systems described herein are for illustrative purposes and, thus, are not intended to be limited to any particular named manufacturer.

What is claimed is:

1. An integrated preassembled solar panel module, comprising
a solar panel configured for receiving and converting solar radiation to produce electrical power;
multiple mounting feet coupled to said solar panel at selected locations; and
one or more sheathing toggle anchors configured for coupling said mounting feet to roof sheathing at locations not overlapping roof rafters and thereby securing said solar panel to said roof sheathing without accessing an underside of said roof sheathing.

2. An integrated preassembled solar panel module as in claim 1, wherein said solar panel comprises a frameless solar panel.

3. An integrated preassembled solar panel module as in claim 1, further comprising multiple integrated brackets coupled to the solar panel in preassembly and configured for coupling to brackets of adjacent solar panel modules of a solar module array.

4. An integrated preassembled solar panel module as in claim 1, further comprising at least one elongated track coupled to the solar panel, and wherein said multiple mounting feet are coupled to said solar panel at selected locations along said at least one elongated track.

5. An integrated preassembled solar panel module as in claim 1, wherein said one or more sheathing toggle anchors comprise a toggle with teeth coupled to a threaded bolt.

6. An integrated preassembled solar panel module as in claim 1, wherein said one or more sheathing toggle anchors comprises a toggle of gauge 0.0615 inch or higher coupled to a threaded bolt.

7. An integrated preassembled solar panel module as in claim 1, wherein said one or more sheathing toggle anchors comprises a toggle of length 2.125 inch or higher coupled to a threaded bolt.

8. An integrated preassembled solar panel module as in claim 1, wherein said one or more sheathing toggle anchors comprise a toggle coupled to a threaded bolt, and a collar comprising a ring concentric with a plug disposed between a hex end and a toggle end of the threaded bolt.

9. An integrated preassembled solar panel module as in claim 1, wherein said one or more sheathing toggle anchors comprise a toggle coupled to a threaded bolt, and a hinged collar disposed between a hex end and a toggle end of the threaded bolt for coupling to and/or uncoupling from the threaded bolt without sliding the hinged collar off either of the hex end or the toggle end.

10. An integrated preassembled solar panel module as in claim 9, wherein said hinged collar comprises a hinged ring concentric with a hinged plug.

11. An integrated preassembled solar panel module as in claim 1, wherein said one or more sheathing toggle anchors comprise a toggle coupled to a threaded bolt, and a collar for coupling the toggle to the threaded bolt.

12. An integrated preassambled solar panel module as in claim 11, wherein said collar comprises pins that couple with the toggle.

13. An integrated preassambled solar panel module as in claim 11, wherein said collar comprises a spring to align the toggle with the threaded bolt.

14. An integrated preassambled solar panel module as in claim 11, wherein said spring comprises a leaf spring.

15. An integrated preassambled solar panel module as in claim 11, wherein said toggle comprises a folded side flange.

16. An integrated preassembled solar panel module as in claim 11, wherein said toggle comprises a side flange that comprises a pair of flat top flanges.

17. An integrated preassembled solar panel module, comprising:
a solar panel preassembled with a front surface configured to collect and convert solar radiation for use as a source of energy and a back surface;
multiple integrated brackets coupled to the solar panel in preassembly and configured for coupling to brackets of adjacent solar panel modules of a solar module array;
wherein each bracket comprises a snap lock configured for coupling adjacent solar panels in an installed array in a closed position and for supporting adjacent solar panels as a stacking element in an open position.

18. An integrated preassembled solar panel module as in claim 17, wherein said snap lock comprises a bumper for supporting adjacent solar panels in a stacking configuration.
